(19) United States
(12) Patent Application Publication
(10) Pub. No.: US 2002/0141347 A1
(43) Pub. Date: Oct. 3, 2002

(54) System and method of reducing ingress noise

(76) Inventors: Jeffrey C. Harp, Los Altos, CA (US); Ernest T. Tsui, Cupertino, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/823,481

(22) Filed: Mar. 30, 2001

(51) Int. Cl. H04N 7/173; H04L 1/00; H04J 1/16; H04J 3/14; G06F 11/00; H04L 12/26; G08C 15/00; G01R 31/08; H04N 5/21; H04N 5/213; H04N 5/217

(52) U.S. Cl. 370/248; 725/124; 348/607

(57) ABSTRACT

A first signal containing a noise characteristic such as ingress, a data signal component, and a known sequence of symbols is transmitted from a client to a headend via a transmission channel within a communication network. A model of the transmission channel in the absence of the noise characteristic is then generated, the known sequence of symbols is applied to the transmission channel model, and the output of the transmission channel model is compared to the received signal to dynamically estimate the noise characteristic. The dynamically estimated noise characteristic is then used to modify the signal either at the client or the headend to reduce the impact of the noise characteristic on the transmitted data.

### FIELD OF THE INVENTION

The field of the invention relates generally to signal processing, signal quality improvement, and symbol detection in a communication network environment. More particularly, the field of the invention relates to a system and method of reducing noise within a communications network. Still more particularly, the field of the invention relates to a system and method of reducing ingress noise within a cable television network.

### BACKGROUND OF THE INVENTION

Noise or interference is a prevalent problem in conventional communication networks. As data rates increase, noise present in transmitted data signals can cause data corruption and transmission failure resulting in significant delays and bandwidth inefficiency. Such noise or interference is particularly harmful in the upstream or “return” path from cable subscribers to a distribution hub or “headend” of a conventional cable television network. Internally, a cable television or community antenna television (CATV) network can generate thermal or “white” noise caused by the random, Gaussian motion of electrons within its cabling and components as well as “multi-path” interference, caused by signal reflections off network terminators, oxidized components, and path discontinuities. Moreover, such networks can contain noise, commonly known as “ingress”, originating from an external source and penetrating the CATV network through path discontinuities, inadequate shielding, or in some cases, electrical induction. Sources of ingress noise are common and may include radio frequency (RF) transmitters, power distribution systems, electrical machinery, household appliances, and natural electrical sources like lightning. Consequently, ingress makes up a large percentage of the total noise found in most CATV networks.

A typical cable or CATV network includes a headend connected to subscriber clients such as cable “settop” boxes, cable modems, telephones, switches and the like through a network of trunk, feeder, and drop lines. A headend may therefore serve as both a distribution hub for signals received from local, broadcast, and satellite television sources and as a link between clients and other voice or data networks such as the Public Switched Telephone Network (PSTN) or the Internet. The various lines of the CATV network are arranged in a “tree” or “branch and tree” topology in which one or more high-capacity trunk lines connect the headend to a group of feeder lines radiating out from the headed. These feeder lines in turn are coupled to subscribers, often hundreds or more per feeder, via drop lines at various locations, called taps, along the feeder's length. Bi-directional amplifiers are included at various points of the network to facilitate the transmission of data upstream from client to headend in the frequency band between approximately 5 and 50 MHz. These bi-directional amplifiers have tendency to accumulate and amplify or “funnel” any noise present in the upstream data signal as it is transmitted to the headend due to the multi-point to point configuration of the upstream path.

The upstream or “return” path of a CATV network is therefore extremely susceptible to noise because of this funneling characteristic, the poor electrical integrity of the cable distribution system between the tap and client, and the abundance of noise sources in the upstream frequency band. Consequently, conventional CATV network systems modulate upstream channels less heavily than downstream channels because of their increased susceptibility to noise. For example, conventional CATV networks typically utilize QPSK (quaternary phase shift keying) or QAM-16 (quadrature amplitude modulation) in the upstream direction as compared with QAM-64 or 256 for downstream channels. The upstream bandwidth for each individual subscriber and the total number of subscribers that can be served by a given network infrastructure are both therefore limited by the presence of noise in the upstream data channel.

### BRIEF DESCRIPTION OF THE DRAWINGS

The present invention is illustrated by way of example and not limitation in the figures of the accompanying drawings, in which

FIG. 1 illustrates a system diagram of a conventional cable television network.

FIG. 2 illustrates a high-level block diagram of a cable modem useable with the present invention.

FIG. 3 illustrates a high-level block diagram of a first embodiment of the upstream path of a cable television network.

FIG. 4 illustrates a high-level block diagram of a second embodiment of the upstream path of a cable television network.

FIG. 5 illustrates a high-level block diagram of a third embodiment of the upstream path of a cable television network.

FIG. 6 illustrates a high-level block diagram of a fourth embodiment of the upstream path of a cable television network.

FIG. 7 illustrates a high-level logic flowchart depicting one embodiment of the present invention.

### DETAILED DESCRIPTION OF THE INVENTION

A system and method of reducing ingress noise within a cable television network is disclosed. In the following detailed description, numerous specific details are set forth in order to provide a thorough understanding of the present invention. However, it will be apparent to one of ordinary skill in the art that these specific details need not be used to practice the present invention. In other circumstances, well-known structures, materials, circuits, processes and interfaces have not been shown or described in detail in order not to unnecessarily obscure the present invention.

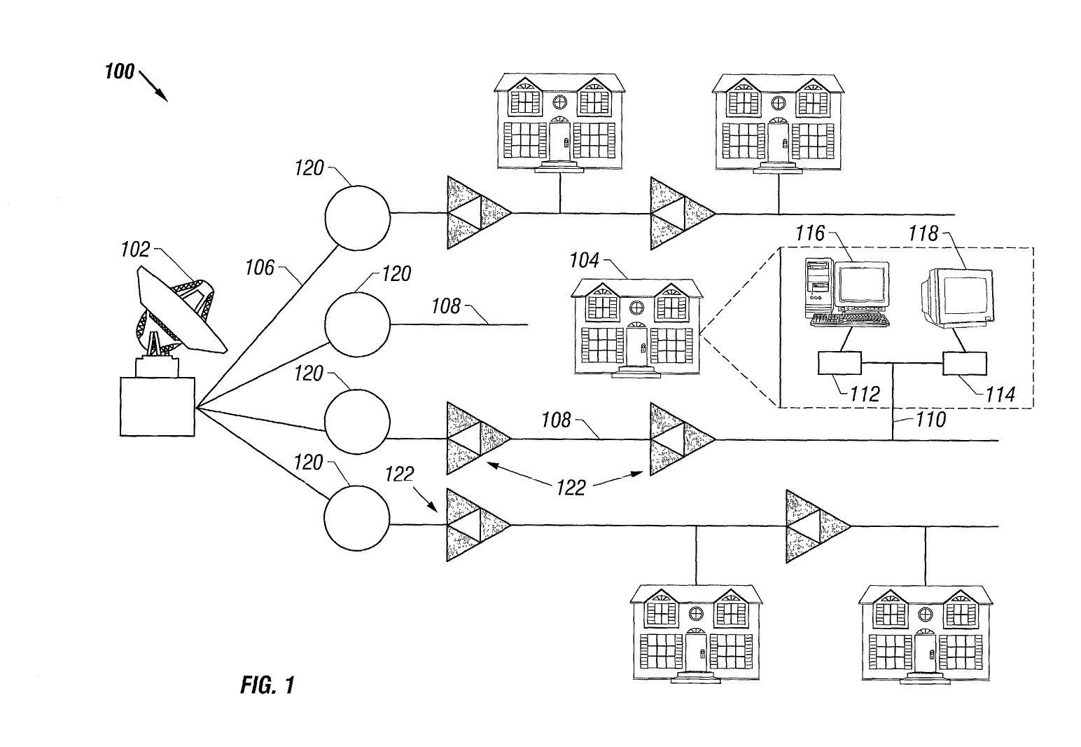

Referring now to FIG. 1, a system diagram of a conventional cable television network is illustrated. CATV network 100 contains a headend 102 and number of residential or commercial subscribers 104 coupled to one another via a series of network lines 106-110. Each subscriber location 104 contains one or more network devices such as personal computer 116 and television 118 coupled to a network drop line 110 via an associated network client such as cable modem 112 or set top box 114. In an alternative embodiment, a network of two or more computers 116 is coupled to drop line 110 via a cable modem 112 or similar client device and a hub or gateway (not shown). Subscriber location 104 may also contain a splitter (not shown) to permit two or more such devices to be connected to a single drop line 110. Drop cable 110 is in turn connected to a feeder cable 108 through a tap (not shown). Composed of coaxial cable like drop line 110, feeder lines 108 run for greater distances than drop lines 110 and therefore require signal amplification by one or more bi-directional amplifiers 122. Feeder lines 108 are sometimes referred to as the CATV system's distribution network or the “last mile” between the network trunks 106 and the customer's premises 104. Although the method and system of the present invention could be implemented in various other tree or branch-and-tree networks such as a traditional, all-coax cable television network, in FIG. 1 a hybrid-fiber-coax (HFC) CATV network is illustrated. The use of multiple fiber trunks 106 between headend 102 and feeder lines 108 allows a greater number or subscribers to be served at greater distances from the headend and eliminates the need to install or maintain costly amplifiers 122 in the trunk section 106. A fiber trunk 106 is coupled to a feeder line 108 using a fiber node 120 which translates signals between optical (trunk 106) and electrical (feeder 108) formats. Headend 102 contains television distribution equipment and a cable modem termination system (CMTS) (not shown). While headend's 102 television distribution equipment is used to receive and distribute television programming from local, broadcast, and satellite sources, the CMTS of headend 102 is used to route data between the system's 100 cable modems 112 and proprietary or public networks such as the Internet. In an alternative embodiment, headend 102 includes a switch (not shown) to connect the network 100 to a voice network such as the public switched telephone network (PSTN).

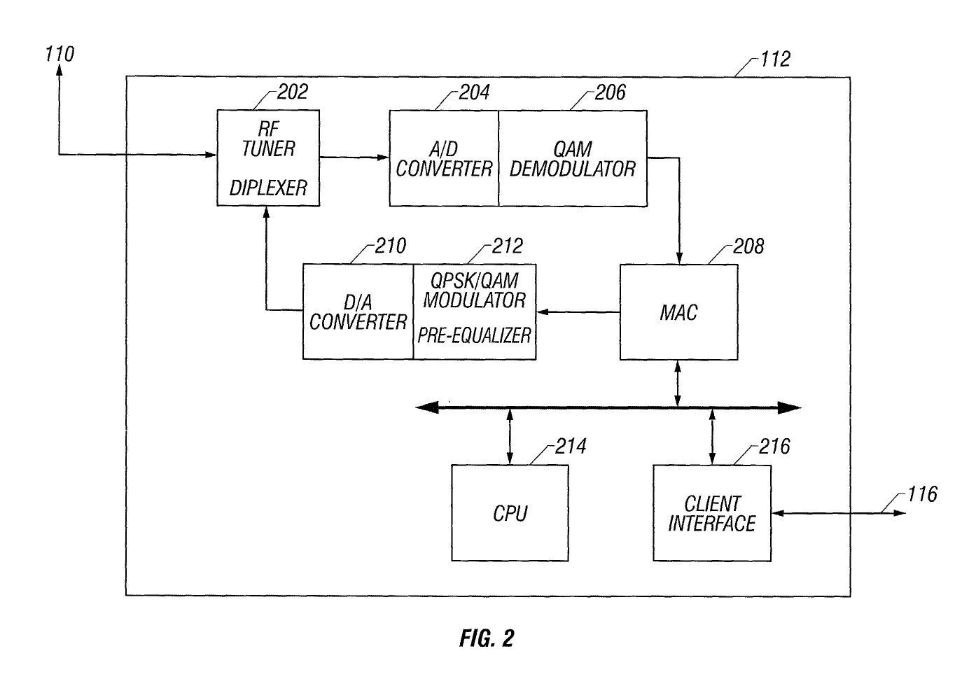

Referring now to FIG. 2, a high-level block diagram of a cable modem (CM) 112 useable with the present invention is illustrated. In a receive path, cable modem 112 includes a combination diplexer and radio frequency tuner 202, an analog-to-digital (A/D) converter 204, a demodulator 206, and a media access control (MAC) device 208. In a transmit path, cable modem 112 includes MAC device 208, a digital-to-analog (D/A) converter 210, a dual modulator and pre-equalizer 212 and a tuner/diplexer 202. Tuner/diplexer 202 allows cable modem 112 to isolate upstream and downstream transmissions within various frequency bands or channels to and from the network through drop line 110. Received signals are then demodulated by demodulator 206 following conversion from analog to digital format by A/D converter 204. Most modem CATV network systems utilize either 64 or 256-QAM modulation techniques which yield between a 30 and 40 Megabit per second (Mbps) bandwidth in a standard 6 Megahertz (MHz) wide channel for downstream transmissions. Accordingly, a QAM demodulator 206 has been illustrated although various modulation techniques have been proposed and implemented and are contemplated by alternative embodiments of the present invention. Similarly, in many CATV systems demodulator 206 may perform additional functions such as MPEG frame synchronization and Reed-Solomon error correction. Although A/D converter 204 and QAM demodulator 206 have been illustrated as two distinct devices, in an alternative embodiment, these devices, as well as other illustrated devices, may be integrated into a single device, circuit, or chip.

Once a received signal has been demodulated it is received by MAC device 208. MAC 208 arbitrates the network transmission medium to avoid data collisions and resolve any collisions that occur. Due to the multi-point to point nature of the CATV network's upstream path, the majority of the arbitration and conflict resolution work done by MAC 208 occurs for reverse or upstream path transmissions. MAC 208 assigns upstream frequencies and data rates, allocates time slots, and performs ranging to calibrate the CM's transmit level and time reference in addition to performing other functions. The transmit path of cable modem 112, including D/A converter 210 and modulator/pre-equalizer 212, performs the receive path process essentially in reverse. Digital signals received from MAC 208 are first modulated by modulator 212 and then converted to analog form by D/A converter 210. Equalization is also performed within the transmit path by pre-equalizer 212. In one embodiment, pre-equalizer 212 contains feed-forward and feedback filter portions to amplify or damp various components of a transmitted signal. The majority of CATV networks modulate upstream transmissions using QPSK or 16-QAM modulation due to the increased susceptibility of the upstream channel to noise described herein. Accordingly, a QPSK/QAM modulator 212 has been illustrated although other known modulation techniques are contemplated and may be facilitated by embodiments of the present invention. This lower degree of modulation typically yields a 6 MHz channel bandwidth of between 320 Kilobits (Kbps) and 10 Megabits per second. An additional function performed by modulator 212 is Reed-Solomon encoding to facilitate error detection and correction in received signals. Cable modem 112 further includes a processor 214 to assist other CM devices such as MAC 208 by performing various functions. In alternative embodiments, such assistance may be provided by a host processor of personal computer 116 or omitted entirely, with the remaining devices performing all of the functions necessary to signal transmission and reception. Interface 216 of cable modem 112 couples the CM to a host such as personal computer 116 and translates data passing between MAC 208 and host 116 to and from various formats such as PCI, Ethernet, or USB.

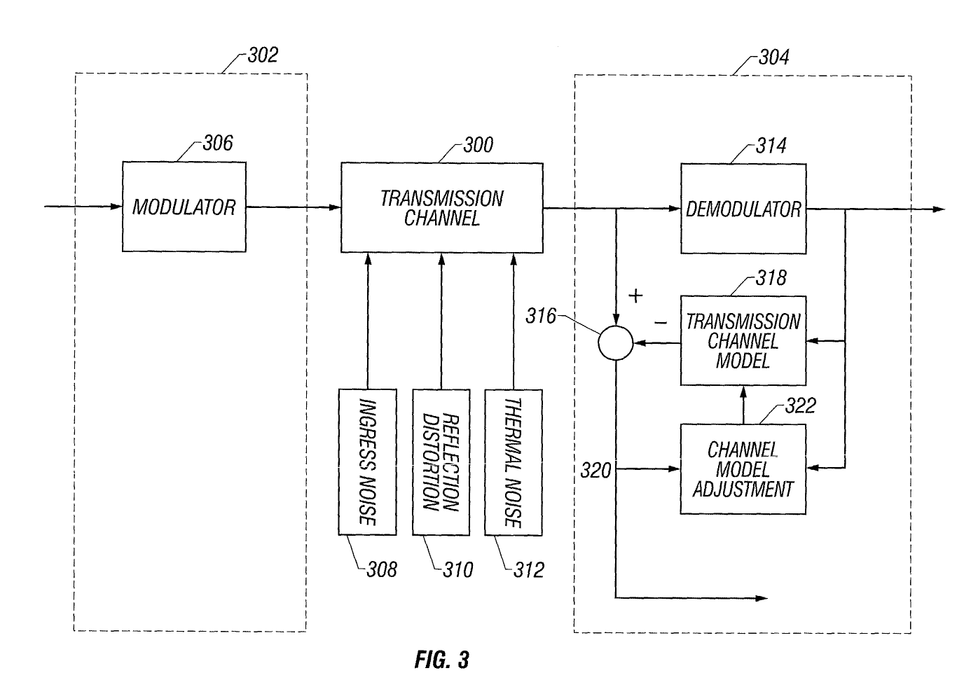

Referring now to FIG. 3, a high-level block diagram of a first embodiment of the upstream path of a CATV “cable” network is depicted. Although discrete devices have been depicted in FIGS. 3-6, it will be readily appreciated by those of ordinary skill that executable software or firmware routines, instructions, or the like stored within a machine readable medium and coupled with a general or special purpose processor (not shown) may be substituted therefore without departing from the spirit and scope of the embodiments illustrated. A machine-readable medium may include any mechanism that provides (i.e., stores and/or transmits) data in a form readable by a machine, data processing system or computer. For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, etc.); or the like. In one embodiment of the present invention, a machine-readable medium, such as a computer-readable disk is provided, having a plurality of machine-executable instructions embodied therein which when executed by a machine, cause said machine to perform the method of the present invention.

As illustrated in FIG. 3, a first signal containing a data component and a known sequence of symbols such as a pseudo-random training sequence, a preamble, or a sequence of correctly-detected data symbols is transmitted from a client 302 such as cable modem 112 or cable set top box 114 to a headend 304 via a transmission channel 300 after being modulated utilizing a modulator 306 such as QPSK modulator 212. In one embodiment of the present invention, the transmitted signal encompasses a burst signal transmission, such as a time division multiple access (TDMA) signal utilized in various cable, wireline, and wireless systems, including a preamble prepended to a data signal transmission. In an alternative embodiment, a continuous wideband wireless signal is transmitted, such as a high definition television (HDTV) signal, including both a data signal and an imbedded, periodically repeating training signal. This first signal is then received by headend 304 and applied to a demodulator 314 such as a bulk QPSK demodulator.

Under ideal conditions, signals received by headend 304 via transmission channel 300 would be identical to those transmitted from client 302, having unity gain and no distortion. However, as FIG. 3 illustrates, several additive noise components are present in or injected into transmission channel 300 such as ingress noise 308, path or “reflection” distortion 310, and thermal or “white” noise 312. In the illustrated embodiment, the data signal and known symbol sequence components of the first signal are transmitted substantially simultaneously from client 302 to headend 304, allowing a noise characteristic to be identified in the presence of an information-bearing data signal. In lieu of this “look-through” technique, data transmission must be interrupted, either by briefly shutting off all transmitted signals or replacing a transmitted data signal with a known symbol sequence in order for a noise component such as ingress noise 308 to be observed and characterized. For time-varying noise components like ingress 308, this interruption would have to be frequently repeated, thus significantly reducing the efficiency of the transmission channel and the network as a whole.

Accordingly, the first signal is processed to produce a second signal including the known symbol sequence, which is in turn used to excite a transmission channel model 318 representative of the transmission channel 300 in the absence of ingress 308 and thermal or white Gaussian noise 312. The output of the transmission channel model 318 is then compared to the received first signal utilizing comparator 316. For purposes of this comparison, the first signal is synchronously sampled, relative to the symbol rate of the known symbol sequence, and its carrier is removed using a tracking phase-lock loop (PLL) (not shown). In a first embodiment this processing of the first signal entails demodulation utilizing a demodulator 314 to extract the known sequence of symbols. In an alternative embodiment, a copy of the known symbol sequence is stored within a machine-readable medium such as a read-only memory and the second signal is produced by processing or “correlating” the received first signal with the known symbol sequence to determine the nominal position of known symbols within the first signal.

Transmission channel model 318 includes a finite impulse response (FIR) filter which, when excited with the known sequence of symbols, produces an output which is an optimum estimate of the received signal in a minimum mean square error sense. The finite impulse response filter of transmission channel model 318 has a spacing parameter associated with it and a plurality of coefficients or “taps” computed utilizing a least squares (LS) algorithm. “Tap” or coefficient spacing describes the time interval between data samples residing in adjacent taps. In one embodiment of the present invention, the computation is adaptive, implementing a recursive least squares (RLS), fast recursive least squares (fast RLS), or least mean square (LMS) method. In an alternative, more precise and computationally intensive embodiment, a direct least squares computation of the transmission channel model filter is performed.

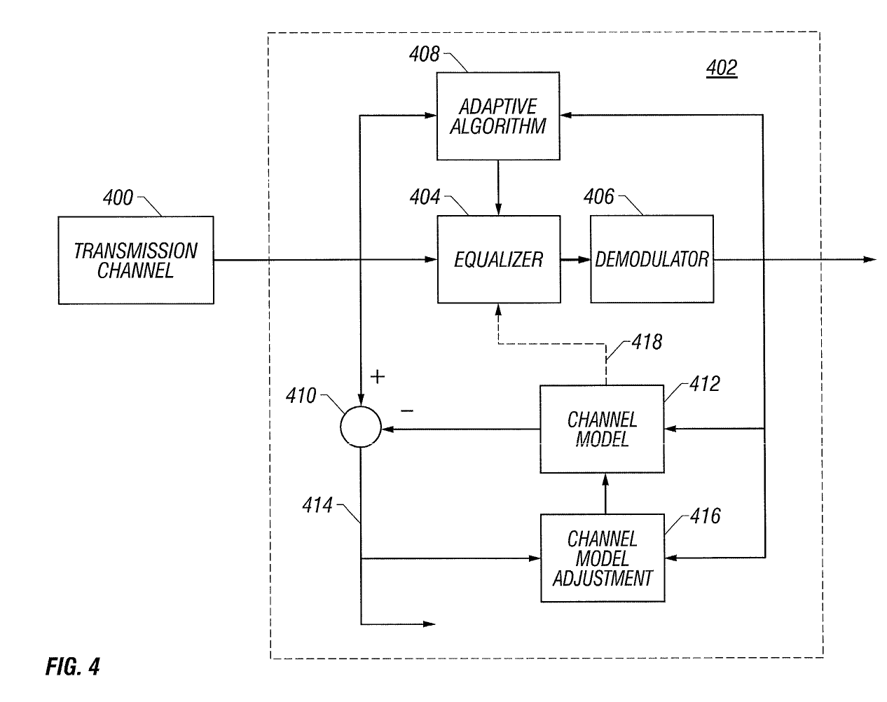

Consequently, the difference between the transmission channel model 318 output and the received components of the first signal, provided at an output 320 of comparator 316, provides a dynamic estimate of various noise characteristics, such as ingress noise 308 and “thermal” or additive white Gaussian noise 312 present within the transmission channel 300. This difference 320 thus also represents one or more noise characteristics of data signals transmitted via the transmission channel 300. In the illustrated embodiment, an adaptive adjustment 322 of the transmission channel model 318 is performed utilizing the output 320 of comparator 316 and the known symbol sequence to improve the accuracy of transmission channel model 318. The output 320 of comparator 316 may similarly be used to determine a signal to noise ratio (SNR) of the transmitted data signal as well as for other purposes further described herein with reference to FIGS. 4-6.

Referring now to FIG. 4, a high-level block diagram of a second embodiment of the upstream path of a cable television network is depicted. Like the upstream path illustrated by FIG. 3, the transmission path depicted by FIG. 4 includes a noise characteristic-susceptible transmission channel 400 capable of carrying a first signal including a data signal component and a known sequence of symbols substantially simultaneously from a client (not shown) to a headend 402. Similarly, headend 402 includes a demodulator 406, a comparator 410, and a transmission channel model 412 including a FIR filter, all operating as described with reference to FIG. 3. Also included within headend 402 of the illustrated embodiment however is an equalizer 404 such as an adaptive decision feedback equalizer (DFE), including a plurality of coefficients. As previously described with respect to FIG. 3, the first signal is processed to produce a second signal including the known symbol sequence which is applied to the transmission channel mod el 412 in the embodiment depicted in FIG. 4. The output of transmission channel model 412 is then similarly compared with the carrier-stripped, synchronously-sampled first signal to dynamically estimate a noise characteristic present within the transmission medium 400 and consequently within the transmitted data signal.

The noise estimate 414 may then be utilized in addition to the known symbol sequence to perform an adaptive channel model adjustment 416 to transmission channel model 412 and is further utilized to initialize and adaptively update the value of each coefficient within equalizer 404. In the illustrated embodiment, the noise estimate 414 is applied to an adaptive algorithm 408, such as a RLS, Fast RLS, or LMS algorithm which is utilized to originally calculate and subsequently revise the value of each of the equalizer's 404 coefficients. In another embodiment of the present invention the value of each coefficient is computed directly. In the illustrated embodiment, received data signal components may then be applied to equalizer 404 to amplify or damp various portions of the signal in order to reduce the estimated noise characteristic. In an alternative embodiment, substitute methods of combating transmission channel interference using the dynamically estimated noise characteristic 414 are contemplated, such as the implementation of a frequency-agile system.

The plurality of coefficients or “taps” of equalizer 404 are allocated between feed-forward (FFE) and feedback (FBE) equalizer sections. This sharing or “partition” of coefficients between the FFE and FBE sections, as well as the total number of taps, the tap spacing, and the location of the principal forward tap are each part of the configuration of equalizer 404. In the illustrated embodiment, equalizer 404 is configured utilizing an impulse response 418 of the FIR filter of transmission channel model 412. The filter's impulse response 418 includes a description of the number of multipath components of the transmission channel model 412, their strength, and whether their delays are positive (post-cursor or echo) or negative (precursor) relative to the principle channel impulse. The delays and amplitudes of the post-cursor components of the transmission channel model 412 impulse response 418 are utilized to provide a rough sizing of the feedback section of equalizer 404. Similarly, the delays and amplitudes of the precursor components of the transmission channel model 412 impulse response 418 are used to provide a rough sizing of the feed-forward section of equalizer 404 and the location of the principle forward tap of equalizer 404 is estimated as being roughly eight taps from the end of its feed-forward structure.

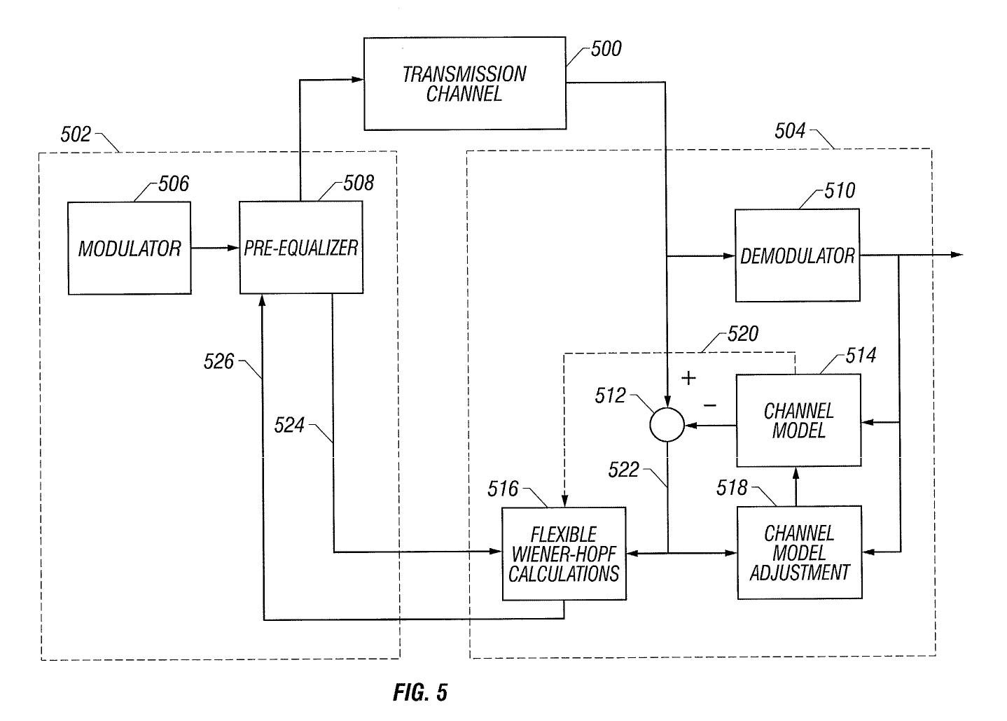

Referring now to FIG. 5, a high-level block diagram of a third embodiment of the upstream path of a cable television network is illustrated. Like the upstream path illustrated in FIG. 4, the transmission path depicted in FIG. 5 includes a noise characteristic-susceptible transmission channel 500 capable of carrying a first signal including a data signal component and a known sequence of symbols substantially simultaneously from a client 502 to a headend 504. Similarly, headend 504 includes a demodulator 510, a comparator 512, and a transmission channel model 514 including a FIR filter, all operating as described with reference to FIG. 4. Furthermore, as previously described, a second signal including the known sequence of symbols produced by processing the received first signal, is applied to a transmission channel model 514 whose output is compared with the carrier-stripped, synchronously-sampled first signal to dynamically estimate a noise characteristic present within the transmission medium 500 and consequently within the transmitted data signal. This noise characteristic estimate 522 is similarly applied in addition to the known symbol sequence to perform a channel model adjustment 518 in order to improve the accuracy of transmission channel model 514. Unlike the embodiment illustrated by FIG. 4 however, signal modification is performed within client 502 rather than headend 504 utilizing a pre-qualizer 508. Pre-equalizer 508 includes a plurality of coefficients allocated among FFE and FBE sections and configuration parameters analogous to those described with reference to equalizer 404 of FIG. 4. In place of the adaptive algorithm 408 of FIG. 4 however, a generalized or “flexible” Wiener-Hopf calculation 516 is performed to initialize and adaptively update the value of each coefficient within pre-equalizer 508.

Utilizing an impulse response 520 of the FIR filter of transmission channel model 514, the estimated noise characteristic 522 of the first signal transmitted via transmission channel 500, and one or more client parameters 524 describing the architecture or pre-distortion capability of pre-equalizer 508 such as the total number of taps, the tap spacing, and the available partition, a solution to flexible Wiener-Hopf calculations 516 is determined. This adaptive Wiener-Hopf 516 solution provides an optimum client pre-equalizer configuration 526 including the best value for each pre-equalizer coefficient for the given channel 500 and equalizer 508 hardware. Once determined, the optimum pre-equalizer configuration 526 is transmitted to client 502 and used to configure a pre-equalizer 508, such as modulator/equalizer 212 of cable modem 112 of FIG. 2, which in turn is utilized to filter or impose distortion on data signal transmissions to reduce associated noise characteristics. In an alternative embodiment, substitute methods of combating transmission channel interference using the dynamically estimated noise characteristic 522 are contemplated, such as the implementation of a frequency-agile system. By filtering or imposing distortion on data signals at the client rather than the headend, the illustrated embodiment reduces the equalization burden traditionally placed on the headend, allowing higher-order modulation techniques such as QAM-64, etc. to be utilized in the upstream direction to produce higher overall upstream bandwidth. This is particularly useful due to the time and client-variable nature of the impact noise characteristics such as ingress 308 have on transmission channels 500 and is mandatory for compliance with the most recent industry standards. Although separate transmission lines 524 and 526 have been illustrated between client 502 and headend 504, in a preferred embodiment of the present invention, the transmission of pre-distortion parameters 524 and the optimum client configuration 526 occurs via the upstream and downstream paths of transmission channel 500 respectively.

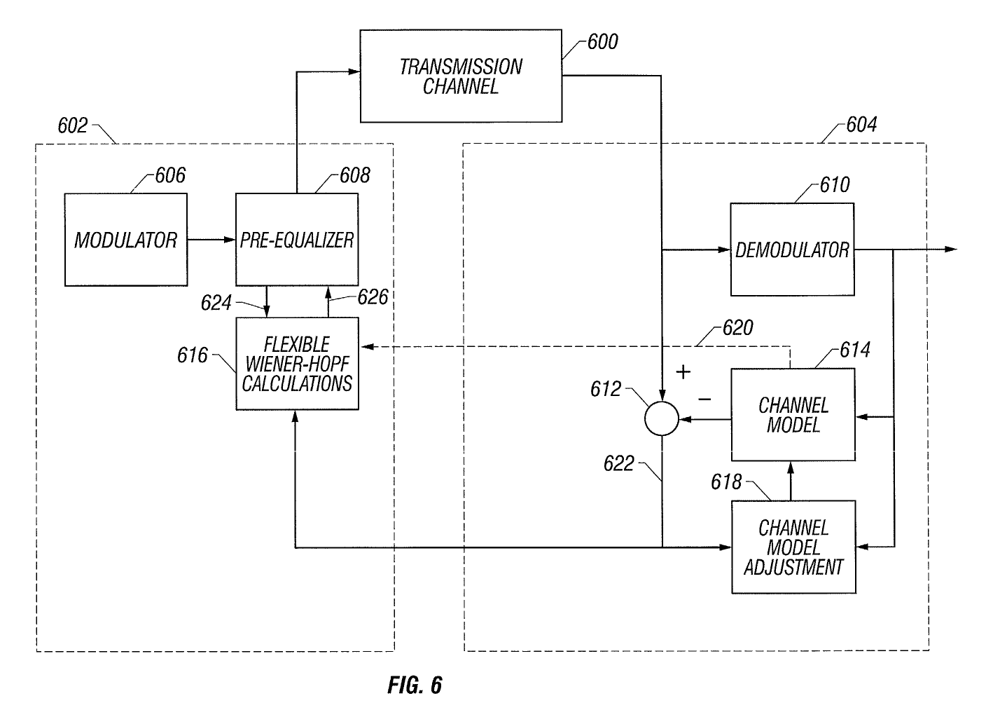

Referring now to FIG. 6, a high-level block diagram of a fourth embodiment of the upstream path of a CATV television network is illustrated. Nearly identical to the upstream path illustrated by FIG. 5, the transmission path depicted in FIG. 6 includes a noise characteristic-susceptible transmission channel 600 capable of carrying a first signal including a data signal component and a known sequence of symbols substantially simultaneously from a client 602 to a headend 604. The upstream path of FIG. 6 also includes a modulator 606, a demodulator 610, a comparator 612, a pre-equalizer 608 and a transmission channel model 614 including a FIR filter, all operating as previously described. Similarly, a second signal including the known symbol sequence, produced by processing the received first signal, is applied to a transmission channel model 614 whose output is compared with the carrier-stripped, synchronously-sampled first signal to dynamically estimate a noise characteristic present within the transmission medium 600 and consequently within the transmitted data signal. This noise characteristic estimate 622 is similarly utilized in addition to the applied known symbol sequence to perform a channel model adjustment 618 in order to improve the accuracy of transmission channel model 614. The embodiment illustrated in FIG. 6 differs however from that of FIG. 5 in that the Wiener-Hopf calculations 616 are performed within the client 602 rather than in the headend 604 as illustrated in FIG. 5, further reducing the burden placed on headend 604. In another alternative embodiment of the present invention a combination of pre-equalization or pre-distortion in the client and equalization in the headend is implemented. Using this alternative method embodiment, specific frequency ranges or bands of a data signal may be amplified or boosted at the client to improve the signal to noise ratio of a transmitted data signal and similarly specific signal damping or filtering may be implemented at the headend to complement client pre-distortion/equalization and further reduce the impact of ingress noise.

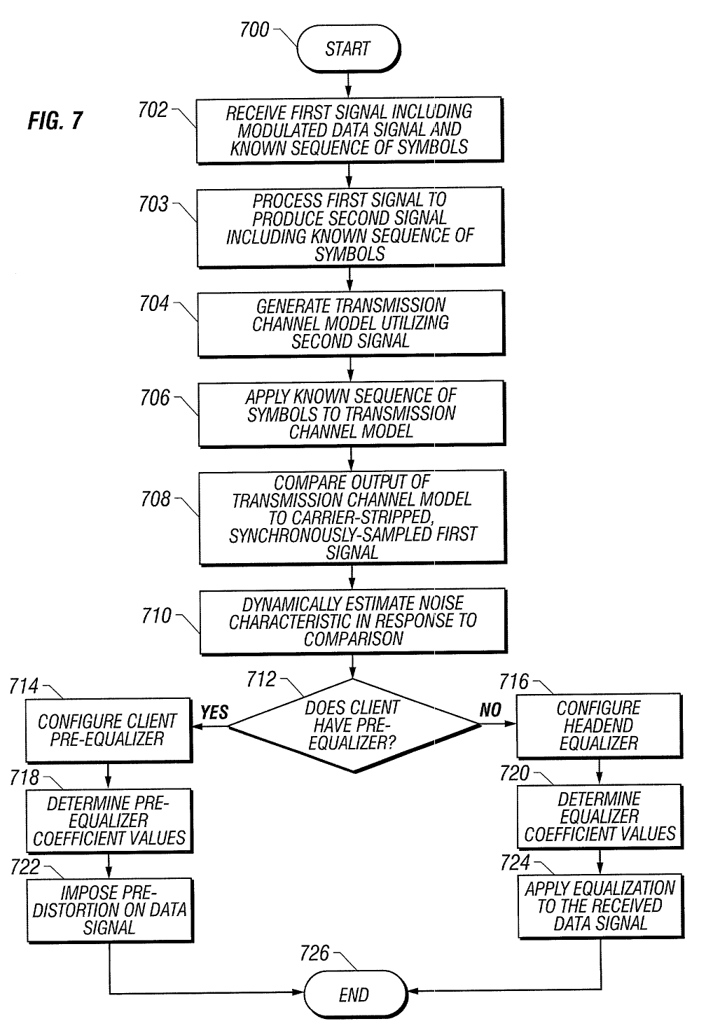

Referring now to FIG. 7, a high-level logic flowchart depicting one embodiment of the present invention is illustrated. FIG. 7 depicts a technique by which a noise characteristic of a data signal transmitted via a transmission channel within a communications network is reduced. The process illustrated by FIG. 7 begins at block 700. Thereafter a first signal including a modulated data signal component and known sequence of symbols is received at a headend of the communication system (block 702). Following its reception, the received first signal is processed to produce a second signal including the known symbol sequence (block 703). Next, a transmission channel model is generated using the resultant second signal (block 704). The known sequence of symbols, either extracted by the demodulation of the first signal or retrieved from storage and correlated with the received first signal, is then applied to the generated transmission channel model (block 706). The carrier signal of the received first signal is then removed and the signal is synchronously sampled and compared to the transmission channel model output (block 708). A noise characteristic of the transmitted signal, such as ingress or additive white Gaussian noise, is then dynamically estimated in response to the performed comparison (block 710). Next it is determined whether the transmitting client has a pre-equalizer providing pre-distortion and/or pre-equalization capability (block 712). If so, a pre-equalizer configuration is generated using impulse response data from the transmission channel model (block 714), the values of each of the pre-equalizer's coefficients is determined (block 718), and the data signal is distorted or equalized prior to transmission utilizing the pre-equalizer (block 722) before the process terminates (block 726). In the event the transmitting client lacks pre-distortion or pre-equalization capability, a headend equalizer is configured (block 716), its coefficient values are determined (block 720), and equalization is applied to the received data signal (block 724) to compensate for the estimated noise characteristic prior to the processes' termination (block 726).

Although the present invention is described herein with reference to a specific preferred embodiment, many modifications and variations therein will readily occur to those with ordinary skill in the art. Accordingly, all such variations and modifications are included within the intended scope of the present invention as defined by the following claims.

What is claimed is:

1. A method comprising:
transmitting a first signal including a data signal from a client to a headend via a transmission channel;
processing said first signal to produce a second signal including a known sequence of symbols;
generating a transmission channel model of said transmission channel independent of a noise characteristic utilizing said second signal;
applying said known sequence of symbols to an input of said transmission channel model;
comparing an output of said transmission channel model to said first signal; and
dynamically estimating a noise characteristic of said data signal at said headend in response to said comparison.

2. The method as set forth in claim 1, wherein transmitting a first signal including a data signal from a client to a headend via a transmission channel comprises:
modulating said data signal and said known sequence of symbols within said client; and
transmitting said data signal and said known sequence of symbols substantially simultaneously from said client to said headend via said transmission channel.

3. The method as set forth in claim 2, wherein:
processing said first signal to produce a second signal including a known sequence of symbols comprises demodulating said first signal to extract said known sequence of symbols, and further wherein:
applying said known sequence of symbols to an input of said transmission channel model comprises applying said extracted known sequence of symbols to said input of said transmission channel model.

4. The method as set forth in claim 2, wherein:
processing said first signal to produce a second signal including a known sequence of symbols comprises:
storing said known sequence of symbols within a memory within said headend;
locating a nominal position of said known sequence of symbols within said first signal;
correlating said first signal with said known sequence of symbols utilizing said nominal position; and
retrieving said known sequence of symbols from said memory in response to said correlation, and further wherein:
applying said known sequence of symbols to an input of said transmission channel model comprises:
applying said retrieved known sequence of symbols to said input of said transmission channel model.

5. The method as set forth in claim 1, wherein said transmission channel model comprises a finite impulse response filter having a plurality of coefficients and generating a transmission channel model of said transmission channel independent of a noise characteristic utilizing said second signal comprises calculating a value for each of said plurality of coefficients of said finite impulse response filter utilizing a least-squares algorithm.

6. The method as set forth in claim 1, wherein dynamically estimating said noise characteristic of said data signal at said headend in response to said comparison comprises estimating an ingress characteristic and a thermal noise characteristic of said data signal.

7. The method as set forth in claim 1, wherein comparing an output of said transmission channel model to said first signal comprises:
synchronously sampling said first signal relative to a symbol rate of said known sequence of symbols and removing a carrier frequency of said first signal to produce a third signal; and
comparing an output of said transmission channel model to said third signal.

8. The method as set forth in claim 5, said method further comprising reducing said noise characteristic of said data signal utilizing said dynamic estimate.

9. The method as set forth in claim 8, wherein reducing said noise characteristic of said data signal utilizing said dynamic estimate comprises:
configuring a filter having a plurality of coefficients;
determining a value for each of said plurality of coefficients; and
modifying said data signal utilizing said filter to reduce said noise characteristic of said data signal.

10. The method as set forth in claim 9, wherein configuring a filter having a plurality of coefficients comprises configuring a filter having a plurality of coefficients utilizing an impulse response of said transmission channel model.

11. The method as set forth in claim 10, wherein:
configuring a filter having a plurality of coefficients comprises configuring a decision-feedback equalizer within said headend, and further wherein:
modifying said data signal utilizing said filter to reduce said noise characteristic of said data signal comprises adaptively filtering said data signal utilizing said decision-feedback equalizer to reduce said noise characteristic of said data signal.

12. The method as set forth in claim 10, wherein:
configuring a filter having a plurality of coefficients comprises:
receiving a pre-equalizer architecture parameter associated with a pre-equalizer within said client; and
generating a pre-equalizer configuration for said pre-equalizer utilizing said pre-equalizer architecture parameter, and further wherein:
modifying said data signal utilizing said filter to reduce said noise characteristic of said data signal comprises imposing distortion on said data signal utilizing said pre-equalizer prior to transmission to reduce said noise characteristic of said data signal.

13. The method as set forth in claim 9, wherein determining a value for each of said plurality of coefficients comprises calculating a value for each of said plurality of coefficients utilizing a Wiener-Hopf equation.

14. A communications network comprising:
a client to transmit a first signal including a data signal via a transmission channel, said client including:
a modulator to modulate said data signal and a known sequence of symbols; and
a transmitter to transmit said modulated data signal and known sequence of symbols substantially simultaneously via said transmission channel;
a headend to receive said first signal via said transmission channel and to dynamically estimate a noise characteristic of said data signal at said headend, said headend including:
a transmission channel model of said transmission channel independent of a noise characteristic to receive a known sequence of symbols;
a processor to process said first signal to produce a second signal including said known sequence of symbols and to provide said known sequence of symbols to said transmission channel model utilizing said second signal; and
a comparator to compare an output of said transmission channel model and said first signal and to dynamically estimate said noise characteristic of said data signal in response to said comparison.

15. The communications network as set forth in claim 14, wherein said noise characteristic comprises an ingress characteristic and a thermal noise characteristic of said data signal.

16. The communications network as set forth in claim 14, wherein said transmission channel model comprises a finite impulse response filter.

17. The communications network as set forth in claim 14, wherein said processor to process said first signal to produce a second signal including said known sequence of symbols and to provide said known sequence of symbols to said transmission channel model utilizing said second signal comprises a bulk demodulator.

18. The communications network as set forth in claim 14, said communications network further comprising a memory to store said known sequence of symbols wherein said processor to process said first signal to produce a second signal including said known sequence of symbols and to provide said known sequence of symbols to said transmission channel model utilizing said second signal comprises a processor to:
locate a nominal position of said known sequence of symbols within said first signal;
correlate said first signal with said known sequence of symbols utilizing a nominal position of said known sequence of symbols within said first signal; and
retrieve said known sequence of symbols from said memory in response to a correlation of said first signal with said known sequence of symbols.

19. The communications network as set forth in claim 14, said communications network further comprising a filter having a plurality of coefficients to reduce said noise characteristic of said data signal utilizing said dynamically estimated noise characteristic.

20. The communications network as set forth in claim 19, said communications network further comprising a processor to configure said filter and to determine a value for each of said plurality of coefficients.

21. The communications network as set forth in claim 20, wherein said processor to configure said filter comprises a processor to generate a filter configuration for said filter utilizing an impulse response of said transmission channel model.

22. The communications network as set forth in claim 21, wherein said filter to reduce said noise characteristic of said data signal comprises a decision-feedback equalizer within said headend of said communications network to adaptively filter said data signal to reduce said noise characteristic of said data signal utilizing said dynamically estimated noise characteristic.

23. The communications network as set forth in claim 21, wherein said filter to reduce said noise characteristic of said data signal comprises a pre-equalizer within said client of said communications network to impose distortion on said data signal prior to transmission of said data signal to reduce said noise characteristic of said data signal utilizing said dynamically estimated noise characteristic.

24. The communications network as set forth in claim 23, wherein said processor to generate a filter configuration for said filter comprises a processor to receive a pre-equalizer architecture parameter associated with said pre-equalizer and to generate a pre-equalizer configuration for said pre-equalizer utilizing said pre-equalizer architecture parameter.

25. A headend comprising:
a receiver to receive a first signal including a data signal from a client via a transmission channel;
a transmission channel model of said transmission channel independent of a noise characteristic to receive a known sequence of symbols;
a processor to process said first signal to produce a second signal including said known sequence of symbols and to provide said known sequence of symbols to said transmission channel model utilizing said second signal; and
a comparator to compare an output of said transmission channel model and said first signal and to dynamically estimate a noise characteristic of said data signal in response to said comparison.

26. The headend as set forth in claim 25, wherein said noise characteristic comprises an ingress characteristic and a thermal noise characteristic of said data signal.

27. The headend as set forth in claim 25, wherein said transmission channel model comprises a finite impulse response filter.

28. The headend as set forth in claim 25, wherein said receiver comprises a receiver to receive a pre-equalizer architecture parameter associated with a client pre-equalizer; said headend further comprising a processor to generate a pre-equalizer configuration for said client pre-equalizer utilizing said pre-equalizer architecture parameter.

29. A machine-readable medium having a plurality of machine-executable instructions embodied therein which when executed by a machine, cause said machine to perform a method comprising:
receiving a first signal including a data signal via a transmission channel;
processing said first signal to produce a second signal including a known sequence of symbols;
generating a transmission channel model of said transmission channel independent of a noise characteristic utilizing said second signal;
applying said known sequence of symbols to an input of said transmission channel model;
comparing an output of said transmission channel model to said first signal; and
dynamically estimating a noise characteristic of said data signal at said headend in response to said comparison.

30. The machine-readable medium as set forth in claim 29, wherein dynamically estimating said noise characteristic of said data signal at said headend in response to said comparison comprises estimating an ingress characteristic and a thermal noise characteristic of said data signal.

31. The machine-readable medium as set forth in claim 29, wherein said method further comprises reducing said noise characteristic of said data signal utilizing said dynamic estimate.
